(19) United States
(12) Patent Application Publication
(10) Pub. No.: US 2011/0084348 A1
(43) Pub. Date: Apr. 14, 2011

(54) MAGNETORESISTANCE ELEMENT, METHOD OF MANUFACTURING THE SAME, AND STORAGE MEDIUM USED IN THE MANUFACTURING METHOD

(75) Inventors: Masaki Kuribayashi, Kawasaki-shi (JP); David Djulianto Djayaprawira, Kawasaki-shi (JP)

(73) Assignee: CANON ANELVA CORPORATION, Kawasaki-shi, Kanagawa (JP)

(21) Appl. No.: 12/996,376

(22) PCT Filed: Aug. 12, 2009
(86) PCT No.: PCT/JP2009/003869

§ 371 Date: Dec. 3, 2010

(30) Foreign Application Priority Data
Sep. 1, 2008 (JP) 2008-223322

(51) Int. Cl. H01L 29/82; H01L 21/02

(52) U.S. Cl. 257/421; 438/3; 257/E29.323; 257/E21.002

(57) ABSTRACT

An embodiment of the invention provides a magnetoresistance element with an MR ratio higher than that of the related art.

A magnetoresistance element includes a first crystalline ferromagnetic layer, a tunnel barrier layer, and a second crystalline ferromagnetic layer. Each of the three layers has a polycrystalline structure including an aggregate of columnar crystals. The tunnel barrier layer is a layer of a metal oxide containing B atoms and Mg atoms. The content of B atoms in the tunnel barrier layer is at least 30 atomic %.

### TECHNICAL FIELD

The present invention relates to a magnetoresistance element used in a magnetic reproducing head of a magnetic disk driving device, a storage element of a magnetic random access memory, and a magnetic sensor, and more particularly, to a tunneling magnetoresistance element (particularly, a spin-valve tunneling magnetoresistance element). In addition, the present invention relates to a method of manufacturing a magnetoresistance element and a storage medium used in the manufacturing method.

### BACKGROUND ART

Patent Literature 1 to 4 and Non-patent Literatures 1 to 5 disclose TMR (tunneling magnetoresistance) elements using a monocrystalline or polycrystalline magnesium oxide film as a tunnel barrier film.

### [Related Art Document]

### [Patent Literature]

Patent Literature 1: Japanese Patent Application

### Laid-Open No. 2003-318465

Patent Literature 2: WO2005/088745

Patent Literature 3: Japanese Patent Application Laid-Open No. 2006-80116

Patent Literature 4: U.S. Patent Application Publication No. 2006/0056115

### [Non-Patent Literature]

Non-patent Literature 1: D. D. Djayaprawira et al., ‘Applied Physics Letters’, 86, 092502 (2005)

Non-patent Literature 2: C. L. Platt et al., ‘J. Appl. Phys.’ 81(8), Apr. 15, 1997

Non-patent Literature 3: W. H. Butler et al., ‘The American Physical Society’ (Physical Review Vol. 63, 054416) Jan. 8, 2001

Non-patent Literature 4: Shinji Yuasa et al., ‘Japanese Journal of Applied Physics’, Vol. 43, No. 48, pp. 588-590, Published on Apr. 2, 2004

Non-patent Literature 5: S. P. Parkin et al., ‘2004 Nature Publishing Group’ Letters, pp. 862-887, Published on Oct. 31, 2004

### DISCLOSURE OF THE INVENTION

An object of the invention is to provide a magnetoresistance element with an MR ratio higher than that of the related art, a method of manufacturing the same, and a storage medium used in the manufacturing method.

According to a first aspect of the invention, a magnetoresistance element includes:

a substrate;

a first crystalline ferromagnetic layer that is provided close to the substrate;

a tunnel barrier layer that is provided on the first crystalline ferromagnetic layer and has a crystal structure of a metal oxide containing B atoms and Mg atoms; and

a second crystalline ferromagnetic layer that is provided on the tunnel barrier layer.

The magnetoresistance element according to the above-mentioned aspect preferably has the preferred following structures.

In the tunnel barrier layer, the content of the B atoms in the metal oxide may be at least 30 atomic %.

The tunnel barrier layer may be a laminated film of an alloy layer containing B atoms and Mg atoms or a metal layer containing Mg atoms and crystal layers of the metal oxide containing the B atoms and the Mg atoms, and the crystal layers are provided on both sides of the alloy layer or the metal layer.

The magnetoresistance element may further include a metal layer containing Mg atoms or an alloy layer containing Mg atom that is provided between the first crystalline ferromagnetic layer and the tunnel barrier layer.

The alloy layer containing the Mg atoms may be an alloy layer containing Mg atoms and B atoms.

The magnetoresistance element may further include a metal layer containing Mg atoms or an alloy layer containing Mg atoms that is provided between the second crystalline ferromagnetic layer and the tunnel barrier layer.

The alloy layer may be an alloy layer containing Mg atoms and B atoms.

Each of the first ferromagnetic layer, the tunnel barrier layer, and the second ferromagnetic layer may have a polycrystalline structure including an aggregate of columnar crystals.

According to a second aspect of the invention, there is provided a method of manufacturing a magnetoresistance element. The method includes: a first step of forming a first ferromagnetic layer with an amorphous structure using a sputtering method; a second step of forming a crystal layer of a metal oxide containing B atoms and Mg atoms on the first ferromagnetic layer using the sputtering method; a third step of forming a second ferromagnetic layer with an amorphous structure on the crystal layer of the metal oxide using the sputtering method; and a fourth step of converting the amorphous structure of the first ferromagnetic layer and the second ferromagnetic layer into a crystal structure.

The method of manufacturing a magnetoresistance element according to the above-mentioned aspect preferably has the following structures.

The fourth step may be an annealing step. In the second step, the crystal layer of the metal oxide containing the B atoms and the Mg atoms may be formed by a sputtering method using a target made of a metal oxide containing B atoms and Mg atoms.

In the second step, the crystal layer of the metal oxide containing the B atoms and the Mg atoms may be formed by a reactive sputtering method using a target made of an alloy containing B atoms and Mg atoms and an oxidizing gas.

According to a third aspect of the invention, there is provided a storage medium that stores a control program for manufacturing a magnetoresistance element using a first sputtering step of forming a first ferromagnetic layer with an amorphous structure, a second sputtering step of forming a crystal layer of a metal oxide containing B atoms and Mg atoms on the first ferromagnetic layer, a third sputtering step of forming a second ferromagnetic layer with an amorphous structure on the crystal layer of the metal oxide, and a crystallizing step of converting the amorphous structure of the first ferromagnetic layer and the second ferromagnetic layer into a crystal structure.

The storage medium according to the above-mentioned aspect preferably has the following structures.

The crystallizing step may be an annealing step.

The second sputtering step may use a target made of a metal oxide containing B atoms and Mg atoms.

The second sputtering step may be a reactive sputtering step using a target made of an alloy containing B atoms and Mg atoms and an oxidizing gas.

According to the invention, it is possible to significantly improve the MR ratio of the tunneling magnetoresistance element (hereinafter, referred to as a TMR element) according to the related art. In addition, the invention can be mass-produced and has high practicality. Therefore, according to the invention, it is possible to provide a memory element of an ultra-large-scale integration MRAM (magnetoresistive random access memory: ferroelectric memory) with high efficiency.

### BRIEF DESCRIPTION OF THE DRAWINGS

FIG. 1 is a cross-sectional view schematically illustrating an example of a magnetoresistance element according to the invention.

FIG. 2 is a diagram schematically illustrating an example of a film forming apparatus that manufactures the magnetoresistance element according to the invention.

FIG. 3 is a block diagram illustrating the apparatus shown in FIG. 2.

FIG. 4 is a perspective view schematically illustrating an MRAM including the magnetoresistance element according to the invention.

FIG. 5 is an equivalent circuit diagram of the MRAM including the magnetoresistance element according to the invention.

FIG. 6 is a cross-sectional view illustrating another example of the tunnel barrier layer according to the invention.

FIG. 7 is a perspective view schematically illustrating the columnar crystal structure of the magnetoresistance element according to the invention.

FIG. 8 is a cross-sectional view illustrating another example of the TMR element of the magnetoresistance element according to the invention.

FIG. 9 is a cross-sectional view illustrating an example of the laminated structure of the magnetoresistance element according to the invention.

### BEST MODE FOR CARRYING OUT THE INVENTION

A magnetoresistance element according to the invention includes a substrate, a first crystalline ferromagnetic layer that is provided close to the substrate, a tunnel barrier layer that is provided on the first crystalline ferromagnetic layer, and a second crystalline ferromagnetic layer that is provided on the tunnel barrier layer. The tunnel barrier layer has the crystal structure of a metal oxide (hereinafter, referred to as a BMg oxide) containing B (boron) atoms and Mg atoms.

In the magnetoresistance element according to the invention, the tunnel barrier layer may include an alloy layer (hereinafter, referred to as a BMg layer) containing B atoms and Mg atoms or a metal layer (hereinafter, referred to as a Mg layer) containing Mg atoms. In this case, a laminated film in which BMg oxide crystal layers formed on both sides of the BMg layer or the Mg layer is provided. In addition, the BMg layer or the Mg layer may be a single layer or two or more layers. When the BMg layer or the Mg layer is two or more layers, a crystalline BMg oxide layer is provided between the layers.

In the tunnel barrier layer according to the invention, the content of B atoms in the metal oxide is preferably 30 atomic % or less, more preferably in the range of 0.01 atomic % to 20 atomic %.

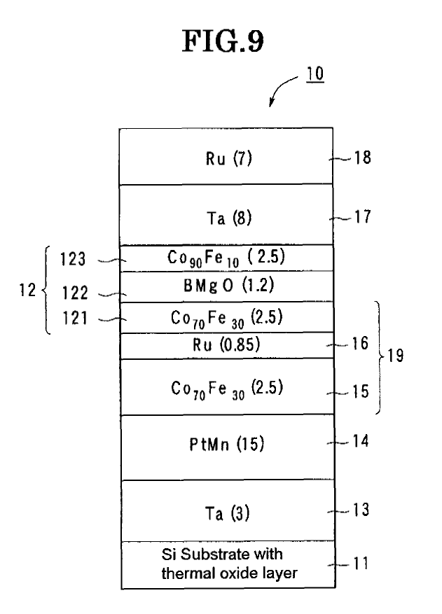

FIG. 9 is a diagram illustrating an example of the laminated structure of the magnetoresistance element according to the invention. A Ta layer, a PtMn layer, a Co₇₀Fe₃₀ layer, a Ru layer, a Co₇₀Fe₃₀ layer, a BMgO layer, a Co₉₀Fe₁₀ layer, a Ta layer, and a Ru layer are laminated on a thermally oxidized Si substrate in this order. In FIG. 9, a numeric value in parentheses of each layer indicates the thickness of the layer and the unit thereof is nanometer.

Table 1 shows an MR ratio depending on the content of B in the BMgO layer of the magnetoresistance element shown in FIG. 9. As can be seen from Table 1, when the content of B is in the range of 0.01 atomic % to 30 atomic %, an MR ratio of about 100% or more is achieved.

TABLE 1

| Content of B(atomic %) | MR ratio(%) |
|---|---|
| 0 | 60 |
| 0.01 | 100 |
| 0.1 | 150 |
| 1 | 180 |
| 5 | 200 |
| 10 | 220 |
| 15 | 230 |
| 20 | 210 |
| 25 | 180 |
| 30 | 140 |
| 35 | 50 |
| 40 | 10 |

The BMg oxide used in the invention is represented by the following formula:

B,Mg_{y}O_{z}(0.7≦Z/(X+Y)≦1.3, preferably, 0.8≦Z/(X+Y)<1.0).

In the invention, it is preferable to use a stoichiometric amount of BMg oxide. However, an oxygen-defective BMg oxide may be used to obtain a high MR ratio.

In the magnetoresistance element according to the invention, a Mg layer or an alloy layer containing Mg atoms (hereinafter, referred to as a Mg alloy layer) is provided between the first ferromagnetic layer and the tunnel barrier layer and/or between the second ferromagnetic layer and the tunnel barrier layer. It is preferable to use BMg as the Mg alloy layer.

It is preferable that the first ferromagnetic layer and the second ferromagnetic layer according to the invention be made of an alloy of Co, Fe, and B (hereinafter, referred to as CoFeB) or an alloy of Co and Fe (hereinafter, referred to as CoFe). In addition, it is preferable that the first ferromagnetic layer and the second ferromagnetic layer be made of an alloy of Co, Fe, and Ni (hereinafter, referred to as CoFeNi) or an alloy of Co, Fe, Ni, and B (hereinafter, referred to as CoFeNiB). It is preferable that the first ferromagnetic layer and the second ferromagnetic layer be made of an alloy of Ni and Fe (hereinafter, referred to as NiFe). In the invention, it is possible to select at least one of the alloy groups.

The first ferromagnetic layer and the second ferromagnetic layer according to the invention may be made of the same alloy or different alloys.

In the magnetoresistance element according to the invention, preferably, each of the first ferromagnetic layer, the tunnel barrier layer, and the second ferromagnetic layer has a polycrystalline structure including an aggregate of columnar crystals (including needle-shaped crystals and cylindrical crystals).

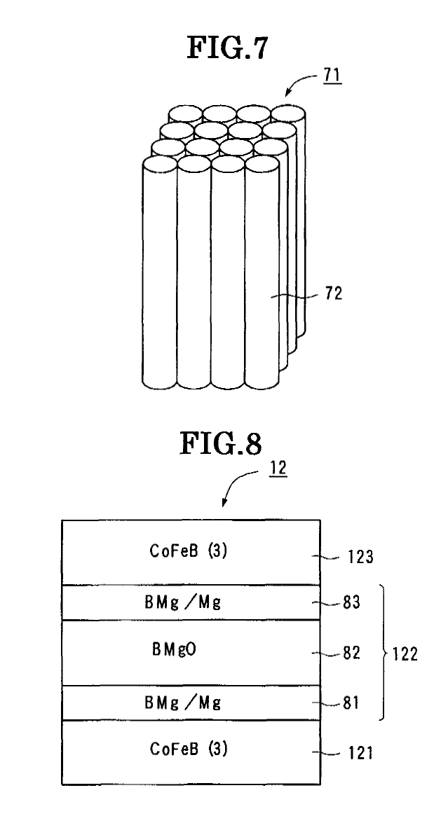

FIG. 7 is a perspective view schematically illustrating a polycrystalline structure including an aggregate 71 of columnar crystals 72 of a BMg oxide. The polycrystalline structure also includes a structure of a polycrystalline-amorphous mixture region having a partial amorphous region in a polycrystalline region. It is preferable that each columnar crystal be a single crystal in which the (001) crystal plane is preferentially arranged in the thickness direction. The average diameter of the columnar single crystals is preferably 10 nm or less, more preferably, in the range of 2 nm to 5 nm. The thickness of the columnar single crystal is preferably 10 nm or less, more preferably, in the range of 0.5 nm to 5 nm.

Next, a method of manufacturing the magnetoresistance element according to the invention will be described. The manufacturing method according to the invention has the following steps:

a first step of forming a first ferromagnetic layer with an amorphous structure using a sputtering method;

a second step of forming a BMg oxide crystal layer on the first ferromagnetic layer using the sputtering method;

a third step of forming a second ferromagnetic layer with an amorphous structure on the BMg oxide crystal layer using the sputtering method; and

a fourth step of converting the amorphous structure of the first ferromagnetic layer and the second ferromagnetic layer into a crystal structure.

In the invention, the first step, the second step, and the third step may be performed by individual sputtering apparatuses. For example, a first sputtering apparatus is used to perform the first step. A substrate is carried from the first sputtering apparatus into a second sputtering apparatus, and the second step is performed by the second sputtering apparatus. Subsequently, the substrate is carried from the second sputtering apparatus into a third sputtering apparatus, and the third step is performed by the third sputtering apparatus. In particular, in the invention, it is preferable that the step of forming the BMg oxide layer and the steps of forming the first and second ferromagnetic layers be performed by different sputtering apparatuses.

It is preferable that the sputtering apparatuses used in the invention be magnetron sputtering apparatuses that apply high-frequency power (for example, RF power) to a target.

In the invention, for example, an annealing step or an ultrasonic wave applying step may be performed as the fourth step. In particular, it is preferable to perform the annealing step. In the annealing step, the amorphous structure of the first ferromagnetic body and the second ferromagnetic body disposed at the interface of the BMg oxide crystal layer starts to be epitaxially grown from the interface to the crystal structure. As a result, a columnar crystal is formed in the thickness direction of the first ferromagnetic layer and the second ferromagnetic layer from the interface.

The annealing step according to the invention is performed for 1 hour to 6 hours (preferably, for 2 hours to 5 hours) at a temperature of 200° C. to 350° C. (preferably, at a temperature of 230° C. to 300° C.). The degree of crystallization of a generated crystal may vary depending on the temperature and the heating time of the annealing step. In the invention, the degree of crystallization per the total volume may be at least 90%. In particular, the degree of crystallization per the total volume may be 100%.

It is preferable that, in the second step, the BMg oxide crystal layer be formed by a sputtering method using a target made of a BMg oxide. In particular, it is preferable that the BMg oxide crystal layer be formed by a reactive sputtering method using the target and an oxidizing gas. For example, preferably, an oxygen gas, an ozone gas, or vapor is used as the oxidizing gas.

Next, a storage medium according to the invention will be described. A control program for manufacturing the magnetoresistance element using the following steps is stared in the storage medium:

a first sputtering step of forming a first ferromagnetic layer with an amorphous structure;

a second sputtering step of forming a BMg oxide crystal layer on the first ferromagnetic layer; and

a third sputtering step of forming a second ferromagnetic layer with an amorphous structure on the metal oxide crystal layer; and

a crystallizing step of converting the amorphous structure of the first ferromagnetic layer and the second ferromagnetic layer into a crystal structure.

It is preferable that the crystallizing step be an annealing step. The second sputtering step is preferably a sputtering step using a target made of a BMg oxide, particularly, a reactive sputtering step using the target and an oxidizing gas. In addition, for example, an oxygen gas, an ozone gas, or vapor is preferably used as the oxidizing gas.

Any kind of media capable of storing the program may be used as the storage medium. For example, a nonvolatile memory, such as a hard disk medium, a magneto-optical disk medium, a floppy (registered trademark) disk medium, a flash memory, or an MRAM, may be used as the storage medium.

Next, exemplary embodiments of the invention will be described in detail.

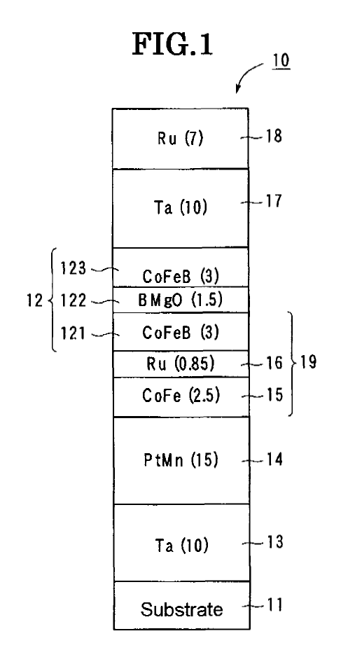

FIG. 1 is a diagram illustrating an example of the laminated structure of a magnetoresistance element 10 using a TMR element 12 according to the invention. The magnetoresistance element 10 includes, for example, nine films containing the TMR element 12 provided on a substrate 11. The nine films form a multi-layer film structure from a first layer (Ta layer), which is the lowest layer, to a ninth layer (Ru layer), which is the uppermost layer. Specifically, magnetic layers and nonmagnetic layers are laminated in the order of a PtMn layer, a CoFe layer, a nonmagnetic Ru layer, a CoFeB layer, a nonmagnetic BMg oxide layer, a CoFeB layer, a nonmagnetic Ta layer, and a nonmagnetic Ru layer. In FIG. 1, a numeric value in parentheses of each layer indicates the thickness of the layer and the unit thereof is nanometer. The thickness of each layer is just an illustrative example, but the invention is not limited thereto. In addition, the PtMn layer is an alloy layer containing Pt atoms and Mn atoms.

In FIG. 1, reference numeral 11 denotes a substrate, such as a wafer substrate, a glass substrate, or sapphire substrate. Reference numeral 12 denotes a TMR element containing a first ferromagnetic layer 121, a tunnel barrier layer 122, and a second ferromagnetic layer 123. Reference numeral 13 denotes a lower electrode layer (base layer), which is the first layer (Ta layer), and reference numeral 14 denotes an antiferromagnetic layer, which is the second layer (PtMn layer). Reference numeral 15 denotes a ferromagnetic layer, which is the third layer (CoFe layer), and reference numeral 16 denotes a nonmagnetic layer for exchange coupling, which is the fourth layer (Ru layer). Reference numeral 121 denotes a ferromagnetic layer, which is the fifth layer (crystalline CoFeB layer). The third layer, the fourth layer, and the fifth layer form a magnetization fixed layer 19. The substantial magnetization fixed layer 19 is the ferromagnetic layer 121, which is the fifth crystalline CoFeB layer, and corresponds to the first ferromagnetic layer according to the invention.

Reference numeral 122 denotes a tunnel barrier layer, which is the sixth layer (polycrystalline BMg oxide), and the tunnel barrier layer is an insulating layer. The tunnel barrier layer 122 may be a single polycrystalline BMg oxide layer.

As shown in FIG. 6, in the invention, a microcrystalline, polycrystalline, or monocrystalline BMg layer or Mg layer 1222 may be provided in the polycrystalline BMg oxide layer. In this case, a laminated structure in which polycrystalline BMg oxide layers 1221 and 1223 are provided on both sides of the BMg or Mg layer 1222 is provided. Two or more BMg or Mg layers 1222 shown in FIG. 6 and the BMg oxide layers may be alternately laminated.

FIG. 8 is a diagram illustrating another example of the TMR element 12 according to the invention. In FIG. 8, reference numerals 12, 121, 122, and 123 denote the same components as those shown in FIG. 1. In this example, the tunnel barrier layer 122 is a laminated film containing a BMg oxide layer 82 and BMg or Mg layers 81 and 83 provided on both sides of the BMg oxide layer 82. In this example, the layer 81 may be a BMg layer and the layer 83 may be a Mg layer. Alternatively, the layer 81 may be a Mg layer and the layer 83 may be a BMg layer. In the invention, the layer 81 may be omitted, and the layer 82 may be arranged adjacent to the crystalline ferromagnetic layer 123. Alternatively, the layer 83 may be omitted, and the layer 82 maybe arranged adjacent to the second ferromagnetic layer 121.

In FIG. 1, reference numeral 123 denotes a crystalline ferromagnetic layer, which is the seventh layer (CoFeB layer) serving as a magnetization free layer, and corresponds to the second ferromagnetic layer according to the invention. The seventh layer 123 may be a crystalline ferromagnetic layer made of polycrystalline NiFe, which is an aggregate of columnar crystals.

It is preferable that the crystalline ferromagnetic layers 121 and 123 be arranged adjacent to the tunnel barrier layer 122 that is provided therebetween. In the manufacturing apparatus, these three layers are sequentially laminated without breaking vacuum.

Reference numeral 17 denotes an electrode layer, which is the eighth layer (Ta layer), and reference numeral 18 denotes a hard mask layer, which is the ninth layer (Ru layer). When the ninth layer is used as a hard mask, it may be removed from the magnetoresistance element.

The ferromagnetic layer 121 (CoFeB layer), which is the fifth layer, in the magnetization fixed layer, the tunnel barrier layer 122, which is the sixth layer (polycrystalline BMg oxide layer), and ferromagnetic layer 123 (CoFeB layer), which is the seventh layer serving as the magnetization free layer, form the TMR element 12.

It is preferable that the tunnel barrier layer 122 (BMg oxide layer), the crystalline ferromagnetic layer 121 (CoFeB layer), and the crystalline ferromagnetic layer 123 each have the columnar crystal structure 71 shown in FIG. 7.

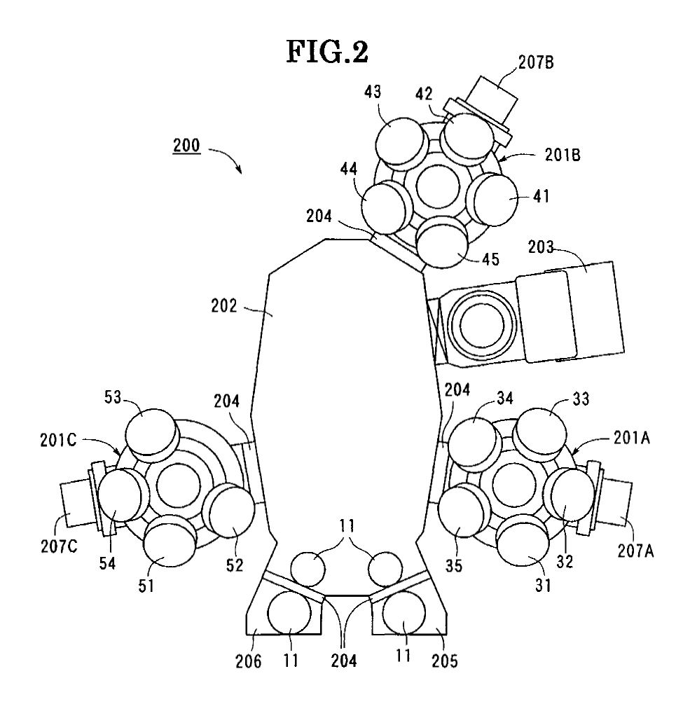

Next, a method and apparatus for manufacturing the magnetoresistance element 10 having the above-mentioned laminated structure will be described with reference to FIG. 2. FIG. 2 is a plan view schematically illustrating an apparatus for manufacturing the magnetoresistance element 10. The apparatus is a sputtering apparatus for mass production capable of manufacturing a multi-layer film containing a plurality of magnetic layers and nonmagnetic layers.

A magnetic multi-layer film manufacturing apparatus 200 shown in FIG. 2 is a cluster-type manufacturing apparatus and includes three film-forming chambers based on a sputtering method. In the apparatus 200, a transport chamber 202 having a robot transport apparatus (not shown) is provided at the center. The transport chamber 202 of the manufacturing apparatus 200 for manufacturing the magnetoresistance element is provided with two load lock and unload lock chambers 205 and 206 by which the substrate (for example, a silicon substrate) 11 is carried in or out. It is possible to reduce the tact time and manufacture a magnetoresistance element with high yield by alternately carrying the substrate in or out from the transport chamber using the load lock and unload lock chambers 205 and 206.

In the manufacturing apparatus 200 for manufacturing the magnetoresistance element, three film-forming magnetron sputtering chambers 201A to 201C and one etching chamber 203 are provided around the transport chamber 202. The etching chamber 203 etches a predetermined surface of the TMR element 10. Gate valves 204 are openably provided between the transport chamber 202 and the chambers 201A to 201C and 203. Each of the chambers 201A to 201C and 202 is provided with, for example, an evacuation mechanism, a gas introduction mechanism, and a power supply mechanism (not shown). The film-forming magnetron sputtering chambers 201A to 201C can deposit the first to ninth layers on the substrate 11 using a radio frequency sputtering method, without breaking vacuum.

Five cathodes 31 to 35, five cathodes 41 to 45, and four cathodes 51 to 54 are arranged on appropriate circumferences of the ceilings of the film-forming magnetron sputtering chambers 201A to 201C, respectively. The substrate 11 is arranged on a substrate holder that is provided coaxially with the circumference. In the magnetron sputtering apparatus, it is preferable that magnets be provided on the rear surfaces of targets mounted on the cathodes 31 to 35, the cathodes 41 to 45, and the cathodes 51 to 54.

In the apparatus, power supply units 207A to 207C apply high-frequency power, such as radio frequency power (RF power), to the cathodes 31 to 35, the cathodes 41 to 45, and the cathodes 51 to 54, respectively. As the radio frequency power, a frequency of 0.3 MHz to 10 GHz, preferably, 5 MHz to 5 GHz, and a power of 10 W to 500 W, preferably, 100 W to 300 W may be used.

For example, a Ta target is mounted on the cathode 31, a PtMn target is mounted on the cathode 32, a CoFeB target is mounted on the cathode 33, a CoFe target is mounted on the cathode 34, and a Ru target is mounted on the cathode 35. In addition, a BMg oxide target or a BMg target is mounted on the cathode 41. When the BMg target is used, a reactive sputtering chamber (not shown) for performing reactive sputtering using an oxidizing gas may be connected to the transport chamber 202.

After a polycrystalline BMg layer is formed by sputtering using a BMg target, the polycrystalline BMg oxide layer may be chemically changed in the oxidation chamber (not shown) using the oxidizing gas (for example, an oxygen gas, an ozone gas, or vapor).

Alternatively, a BMg oxide target may be mounted on the cathode 41 and a BMg target may be mounted on the cathode 42. In this case, no target may be mounted on the cathodes 43 to 45, and the BMg oxide targets or the BMg targets may also be mounted on the cathodes 43 to 45.

A CoFeB target is mounted on the cathode 51, a Ta target is mounted on the cathode 52, and a Ru target is mounted on the cathode 53. In addition, no target may be mounted on the cathode 54, or a CoFeB target, a Ta target, or a Ru target may be appropriately mounted as a reserve target.

It is preferable that the in-plane direction of each of the targets mounted on the cathodes 31 to 35, the cathodes 41 to 45, and the cathodes 51 to 54 be not parallel to the in-plane direction of the substrate. When the non-parallel arrangement is used, it is possible to effectively deposit a magnetic film and a nonmagnetic film with the same composition as a target composition by performing sputtering while rotating a target with a diameter smaller than that of the substrate.

As an example of non-parallel arrangement, the central axis of the target and the central axis of the substrate may be arranged so as to intersect with each other at an angle of 45° or less, preferably, at an angle of 5° to 30°. In this case, the substrate may be rotated at a speed of 10 rpm to 500 rpm, preferably, at a speed of 50 rpm to 200 rpm.

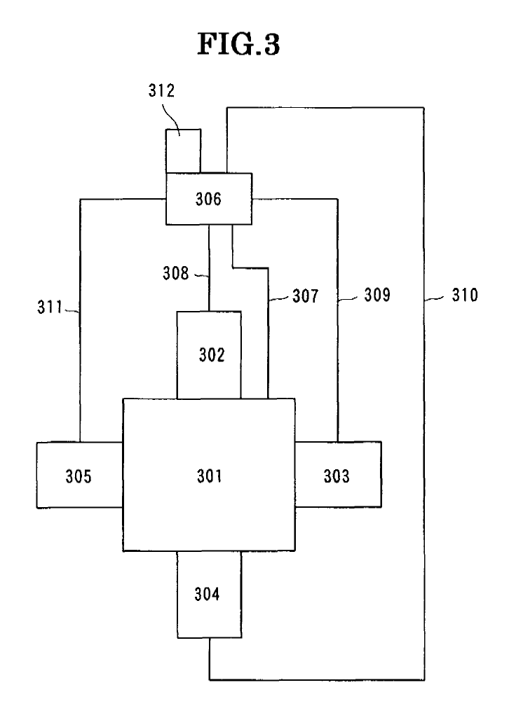

FIG. 3 is a block diagram illustrating the film forming apparatus according to the invention. In FIG. 3, reference numeral 301 denotes a transport chamber corresponding to the transport chamber 202 shown in FIG. 2, reference numeral 302 denotes a film forming chamber corresponding to the film-forming magnetron sputtering chamber 201A, and reference numeral 303 denotes a film forming chamber corresponding to the film-forming magnetron sputtering chamber 201B. In addition, reference numeral 304 denotes a film forming chamber corresponding to the film-forming magnetron sputtering chamber 201C, and reference numeral 305 denotes a load lock and unload lock chamber corresponding to the load lock and unload lock chambers 205 and 206. Reference numeral 306 denotes a central processing unit (CPU) embedded with a storage medium 312. Reference numerals 309 to 311 denote bus lines which connect the CPU 306 and the process chambers 301 to 305 and through which control signals for controlling the operations of the process chambers 301 to 305 are transmitted from the CPU 306 to the process chambers 301 to 305.

In the manufacture of the magnetoresistance element according to the invention, for example, the substrate (not shown) in the load lock and unload lock chamber 305 is carried out into the transport chamber 301. The step of carrying out the substrate is calculated by the CPU 306 on the basis of the control program stored in the storage medium 312. The control signals based on the calculation result are transmitted through the bus lines 307 and 311 to control the operations of various apparatuses in the load lock and unload lock chamber 305 and the transport chamber 301. Various apparatuses include, for example, a gate valve, a robot mechanism, a transport mechanism, and a driving system (not shown). The storage medium 312 corresponds to the above-mentioned storage medium according to the invention.

The substrate transported to the transport chamber 301 is carried out into the film forming chamber 302. The first layer 13, the second layer 14, the third layer 15, the fourth layer 16, and the fifth layer 121 shown in FIG. 1 are sequentially laminated on the substrate in the film forming chamber 302. In this stage, preferably, the CoFeB layer, which is the fifth layer 121, has an amorphous structure. However, the CoFeB layer may have a polycrystalline structure.

The laminating process is performed by transmitting the control signal which is calculated by the CPU 306 on the basis of the control program stored in the storage medium 312 to various apparatuses mounted in the transport chamber 301 and the film forming chamber 302 through the bus lines 307 and 308 to control the operations of the apparatuses. Various apparatuses include, for example, a power supply mechanism that supplies power to the cathodes, a substrate rotating mechanism, a gas introduction mechanism, an exhaust mechanism, gate valves, a robot mechanism, a transport mechanism, and a driving system, which are not shown in the drawings.

The substrate having the laminated film of the first to fifth layers formed thereon returns to the transport chamber 301 and is then carried into the film forming chamber 303. In the film forming chamber 303, a polycrystalline BMg oxide layer is formed as the sixth layer 122 on the amorphous CoFeB layer, which is the fifth layer 121. The sixth layer 122 is formed by transmitting the control signal which is calculated by the CPU 306 on the basis of the control program stored in the storage medium 312 to various apparatuses mounted in the transport chamber 301 and the film forming chamber 303 through the bus lines 307 and 309 to control the operations of the apparatuses. Various apparatuses include, for example, a power supply mechanism that supplies power to the cathodes, a substrate rotating mechanism, a gas introduction mechanism, an exhaust mechanism, gate valves, a robot mechanism, a transport mechanism, and a driving system, which are not shown in the drawings.

The substrate having the first to sixth layers formed thereon returns to the transport chamber 301 and is then carried into the film forming chamber 304. In the film forming chamber 304, the seventh layer 123, the eighth layer 17, and the ninth layer 18 are sequentially formed on the polycrystalline BMg oxide layer, which is the sixth layer 122. In this stage, preferably, the CoFeB layer, which is the seventh layer 123, has an amorphous structure. However, the CoFeB layer may be a polycrystalline structure.

The seventh to ninth layers are formed by transmitting the control signal which is calculated by the CPU 306 on the basis of the control program stored in the storage medium 312 to various apparatuses mounted in the transport chamber 301 and the film forming chamber 304 through the bus lines 307 and 310 to control the operations of the apparatuses. Various apparatuses include, for example, a power supply mechanism that supplies power to the cathodes, a substrate rotating mechanism, a gas introduction mechanism, an exhaust mechanism, gate valves, a robot mechanism, a transport mechanism, and a driving system, which are not shown in the drawings.

Any kind of media capable of storing the program may be used as the storage medium 312 according to the invention. For example, as described above, a nonvolatile memory, such as a hard disk medium, a magneto-optical disk medium, a floppy disk medium, a flash memory, or an MRAM, may be used as the storage medium.

It is possible to carry the laminated film of the first to ninth layers in an annealing furnace (not shown) in order to accelerate the polycrystallization of the amorphous CoFeB layers, which are the fifth layer 121 and the seventh layer 123, by annealing and accelerate the magnetization of the PtMn layer, which is the second layer 14.

A control program for performing the step in the annealing furnace is stored in the storage medium 312. Therefore, it is possible to control various apparatuses (for example, a heater mechanism, an exhaust mechanism, and a transport mechanism, which are not shown in the drawings) in the annealing furnace on the basis of the control signal, which is obtained by the CPU 306 on the basis of the control program, thereby performing the annealing step.

In the invention, alloy layers other than the CoFeB layer may be used as the fifth layer 121 and the seventh layer 123. Specifically, a polycrystalline ferromagnetic layer, such as a CoFeTaZr layer, a CoTaZr layer, a CoFeNbZr layer, a CoFeZr layer, a FeTaC layer, a FeTaN layer, or a FeC layer, maybe used.

In the invention, a Rh layer or an Ir layer may be used, instead of the Ru layer, as the fourth layer 16.

In the invention, it is preferable to use an alloy layer, such as an IrMn layer, an IrMnCr layer, a NiMn layer, a PdPtMn layer, a RuRhMn layer, or an OsMn layer, instead of the PtMn layer, as the second layer 14. In addition, it is preferable that the thickness thereof be in the range of 10 to 30 nm.

In the invention, the polycrystalline CoFeB layer, which is the fifth layer 121, may be a two-layer film of a polycrystalline CoFeB layer and a polycrystalline CoFe layer (which is closer to the substrate). In this case, the polycrystalline CoFe layer arranged closer to the substrate may be formed in a polycrystalline state on the PtMn layer, which is the fourth layer, by a sputtering method.

The inventors found that the CoFeB layer formed subsequent to the polycrystalline CoFe layer has an amorphous structure immediately after sputtering deposition (before the annealing step). Therefore, it is possible to anneal the CoFeB layer with an amorphous structure to change the phase of the CoFeB layer into an epitaxial polycrystalline structure.

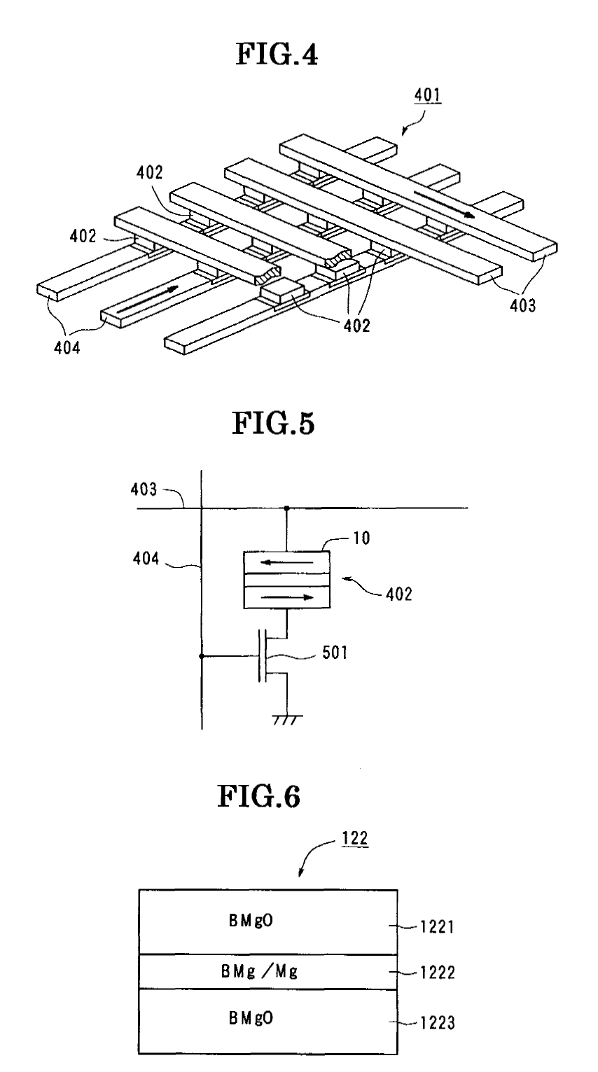

FIG. 4 is a diagram schematically illustrating an MRAM 401 using the magnetoresistance element according to the invention as a memory element. In the MRAM 401, reference numeral 402 denotes a memory element according to the invention, reference numeral 403 denotes a word line, and reference numeral 404 denotes a bit line. A multiple number of memory elements 402 are arranged at intersections of a plurality of word lines 403 and a plurality of bit lines 404 in a lattice shape. Each of the multiple number of memory elements 402 may store 1-bit information.

FIG. 5 is an equivalent circuit diagram of a TMR element 10 that stores 1-bit information and a transistor 501 having a switching function, which are provided at the intersection of the word line 403 and the bit line 404 in the MRAM 401.

### EXAMPLES

The magnetoresistance element shown in FIG. 1 was manufactured by the film forming apparatus shown in FIG. 2. The deposition conditions of the TMR element 12, which is the main component, were as follows.

The ferromagnetic layer 121 was formed by a magnetron DC sputter (chamber 201A) using a target with a CoFeB composition ratio (atomic: atom ratio) of 60/20/20 under the conditions of an Ar gas pressure of 0.03 Pa and a sputter rate of 0.64 nm/sec. In this case, the CoFeB layer (ferromagnetic layer 121) had an amorphous structure. Then, the sputtering apparatus was replaced with another sputtering apparatus(chamber 201B). A target with a BMgO composition ratio (atomic: atom ratio) of 25/25/50 was used and the pressure of a sputter gas was 0.2 Pa in the preferable range of 0.01 Pa to 0.4 Pa. Under the conditions, the tunnel barrier layer 122, which was the BMg oxide layer as the sixth layer, was formed by magnetron RF sputtering (13.56 MHz). In this case, the BMg oxide layer (tunnel barrier layer 122) had a polycrystalline structure made of an aggregate of columnar crystals. In addition, the deposition rate of the magnetron RF sputtering (13.56 MHz) was 0.14 nm/sec.

Then, the sputtering apparatus was replaced with another sputtering apparatus (chamber 201C), and the ferromagnetic layer 123, which was the magnetization free layer (seventh CoFeB layer), was formed. It was found that the CoFeB layer (ferromagnetic layer 123) as the seventh layer had an amorphous structure.

In this example, the deposition rate of the BMg oxide layer was 0.14 nm/sec. However, the BMg oxide layer may be formed at a deposition rate of 0.01 nm/sec to 1.0 nm/sec.

The magnetoresistance element 10 formed by sputtering deposition in each of the film-forming magnetron sputtering chambers 201A to 201C was annealed in a heat treatment furnace in a magnetic field of 8 kOe at a temperature of about 300° C. for 4 hours. As a result, it was found that the amorphous structure of the CoFeB layers, which are fifth and seventh layers, was changed into a polycrystalline structure including the aggregate 71 of the columnar crystals 72 shown in FIG. 7. The annealing step enables the magnetoresistance element 10 to operate having the TMR effect. In addition, predetermined magnetization was given to the antiferromagnetic layer 14, which was the PtMn layer as the second layer, by the annealing step.

As a comparative example of the invention, a magnetoresistance element containing a polycrystalline Mg oxide layer without B atoms was manufactured, instead of the tunnel barrier layer 122, which was a polycrystalline BMg oxide layer and used as the sixth layer 122.

The MR ratio of the magnetoresistance element according to the example and the MR ratio of the magnetoresistance element according to the comparative example were measured and compared. As a result, the MR ratio of the magnetoresistance element according to the example was 1.2 to 1.5 times more than the MR ratio of the magnetoresistance element according to the comparative example.

The BMg oxide of the tunnel barrier layer used in the example was an oxygen-defective BMg oxide represented by the following formula:

BₓMg_{y}O_{z}(Z/(X+Y)=0.95).

The MR ratio is a parameter related to the magnetoresistive effect in which, when the magnetization direction of a magnetic film or a magnetic multi-layer film varies in response to an external magnetic field, the electric resistance of the film is also changed. The rate of change of the electric resistance is used as the rate of change of magnetoresistance (MR ratio).

### DESCRIPTION OF REFERENCE NUMERALS AND SIGNS

10: Magnetoresistance element

11: Substrate

12: TMR element

121: First ferromagnetic layer (fifth layer)

122: Tunnel barrier layer (sixth layer)

123: Second ferromagnetic layer (seventh layer; magnetization free layer)

13: Lower electrode layer (first layer; base layer)

14: Antiferromagnetic layer (second layer)

15: Ferromagnetic layer (third layer)

16: Nonmagnetic layer for exchange coupling (fourth layer)

17: Upper electrode layer (eighth layer)

18: Hard mask layer (ninth layer)

19: Magnetization fixed layer

200: Magnetoresistance element manufacturing apparatus

201A to 201C: Film forming chamber

202: Transport chamber

203: Etching chamber

204: Gate valve

205, 206: Load lock and unload lock chamber

31 to 35, 41 TO 45, 51 TO 54: Cathode

207A to 2070: Power supply unit

301: Transport chamber

302 to 304: Film forming chamber

305: Load lock and unload lock chamber

306: Central processing unit (CPU)

307 to 311: Bus line

312: Storage medium

401: MRAM

402: Memory element

403: Word line

404: Bit line

501: Transistor

71: Aggregate of columnar crystals

72: Columnar crystal

81: BMg layer or Mg layer

82: BMg oxide layer

83: BMg layer or Mg layer

1. A magnetoresistance element comprising:
a substrate;
a first crystalline ferromagnetic layer that is provided close to the substrate;
a tunnel barrier layer that is provided on the first crystalline ferromagnetic layer and has a crystal structure of a metal oxide; and
a second crystalline ferromagnetic layer that is provided on the tunnel barrier layer,
wherein the metal oxide is represented by the following formula: BₓMgₓO_{z}
where x, y, and z satisfy 0.8≦z/(x+y)≦1.0.

2. The magnetoresistance element according to claim 1,
wherein, in the tunnel barrier layer, the content of the B atoms in the metal oxide is at least 30 atomic %.

3. A magnetoresistance element comprising:
a substrate;
a first crystalline ferromagnetic layer that is provided close to the substrate:
a tunnel barrier layer that is provided on the first crystalline ferromagnetic layer and has a crystal structure of a metal oxide containing B atoms and Mg atoms; and
a second crystalline ferromagnetic layer that is provided on the tunnel barrier layer,
wherein the tunnel barrier layer is a laminated film of an alloy layer containing B atoms and Mg atoms or a metal layer containing Mg atoms and crystal layers of the metal oxide containing B atoms and Mg atoms, and the crystal layers are provided on both sides of the alloy layer or the metal layer.

4. A magnetoresistance element according to claim 1, further comprising:
a substrate:
a first crystalline ferromagnetic layer that is provided on the substrate;
a tunnel barrier layer that is provided on the first crystalline ferromagnetic layer and has a crystal structure of a metal oxide containing B atoms and Mg atoms;
a second crystalline ferromagnetic layer that is provided on the tunnel barrier layer; and
a metal layer containing Mg atoms or an alloy layer containing Mg atoms that is provided between the first crystalline ferromagnetic layer and the tunnel barrier layer.

5. The magnetoresistance element according to claim 4,
wherein the alloy layer containing the Mg atoms is an alloy layer containing Mg atoms and B atoms.

6. A magnetoresistance element comprising:
a substrate;
a first crystalline ferromagnetic layer that is provided close to the substrate;
a tunnel barrier layer that is provided on the first crystalline ferromagnetic layer and has a crystal structure of a metal oxide containing B atoms and Mg atoms;
a second crystalline ferromagnetic layer that is provided on the tunnel barrier layer; and
a metal layer containing Mg atoms or an alloy layer containing Mg atoms that is provided between the second crystalline ferromagnetic layer and the tunnel barrier layer.

7. The magnetoresistance element according to claim 6,
wherein the alloy layer is an alloy layer containing Mg atoms and B atoms.

8. The magnetoresistance element according to any one of claims 1 to 7,
wherein each of the first ferromagnetic layer, the tunnel barrier layer, and the second ferromagnetic layer has a polycrystalline structure including an aggregate of columnar crystals.

9. A method of manufacturing a magnetoresistance element, comprising:
a first step of forming a first ferromagnetic layer with an amorphous structure using a sputtering method;
a second step of forming a crystal layer of a metal oxide on the first ferromagnetic layer using the sputtering method;
a third step of forming a second ferromagnetic layer with an amorphous structure on the crystal layer of the metal oxide using the sputtering method; and
a fourth step of converting the amorphous structure of the first ferromagnetic layer and the second ferromagnetic layer into a crystal structure,
wherein the metal oxide is represented by the following formula: BₓMg_{y}O_{z}
where x, y, and z satisfy 0.8≦z/(x+y)≦1.0.

10. The method of manufacturing a magnetoresistance element according to claim 9,
wherein the fourth step is an annealing step.

11. The method of manufacturing a magnetoresistance element according to claim 9,
wherein, in the second step, the crystal layer of the metal oxide represented by the formula is formed by a sputtering method using a target made of a metal oxide containing B atoms and Mg atoms.

12. The method of manufacturing a magnetoresistance element according to claim 9,
wherein, in the second step, the crystal layer of the metal oxide represented by the formula is formed by a reactive sputtering method using a target made of an alloy containing B atoms and Mg atoms and an oxidizing gas.

13. A storage medium that stores a control program for manufacturing a magnetoresistance element using a first sputtering step of forming a first ferromagnetic layer with an amorphous structure, a second sputtering step of forming a crystal layer of a metal oxide on the first ferromagnetic layer, a third sputtering step of forming a second ferromagnetic layer with an amorphous structure on the crystal layer of the metal oxide, and a crystallizing step of converting the amorphous structure of the first ferromagnetic layer and the second ferromagnetic layer into a crystal structure,
wherein the metal oxide is represented by the following formula: BₓMg_{y}O_{z}
where x, y, and z satisfy 0.8≦z/(x+y)≦1.0.

14. The storage medium according to claim 13,
wherein the crystallizing step is an annealing step.

15. The storage medium according to claim 13,
wherein the second sputtering step uses a target made of a metal oxide containing B atoms and Mg atoms.

16. The storage medium according to claim 13,
wherein the second sputtering is a reactive sputtering step using a target made of an alloy containing B atoms and Mg atoms and an oxidizing gas.
